(19) United States
(12) Patent Application Publication
(10) Pub. No.: US 2023/0199974 A1
(43) Pub. Date: Jun. 22, 2023

(54) PRINTED CIRCUIT BOARD AND METHOD FOR MANUFACTURING THE SAME

(71) Applicant: SAMSUNG ELECTRO-MECHANICS CO., LTD., Suwon-si (KR)

(72) Inventors: Chan Hoon KO, Suwon-si (KR); Kee Su JEON, Suwon-si (KR); Ki Eun CHO, Suwon-si (KR); Min Jae SEONG, Suwon-si (KR)

(73) Assignee: SAMSUNG ELECTRO-MECHANICS CO., LTD., Suwon-si (KR)

(21) Appl. No.: 17/698,339

(22) Filed: Mar. 18, 2022

(30) Foreign Application Priority Data
Dec. 21, 2021 (KR) 10-2021-0184002

(51) Int. Cl. H05K 3/46; H05K 1/11; H05K 1/18

(52) U.S. Cl. CPC H05K 3/4644; H05K 1/115; H05K 1/183; H05K 3/4697; H05K 2201/09563

(57) ABSTRACT

A printed circuit board including: a first insulating layer; a first wiring layer disposed on an upper surface of the first insulating layer, and including a first wiring portion and a second wiring portion; and a second insulating layer disposed on the upper surface of the first insulating layer, having a cavity exposing an upper surface of the second wiring portion, and including a first insulating portion covering the first wiring portion and a second insulating portion whose upper surface is exposed from the cavity, wherein one or more gaps are provided between the second wiring portion and the second insulating portion.

### CROSS-REFERENCE TO RELATED APPLICATION(S)

This application claims benefit of priority to Korean Patent Application No. 10-2021-0184002 filed on Dec. 21, 2021 in the Korean Intellectual Property Office, the disclosure of which is incorporated herein by reference in its entirety.

### TECHNICAL FIELD

The present disclosure relates to a printed circuit board, for example, a printed circuit board having a cavity allowing an electronic component to be disposed therein, and a method for manufacturing the same.

### BACKGROUND

Recently, as mobile devices are required to secure greater battery capacity and perform multiple functions, there has been a demand for light, thin, short, and small components. In accordance with this demand, a cavity substrate has been developed as a way of reducing a thickness of a package. Meanwhile, in a general cavity processing method such as blast processing, since a cavity is formed by physically damaging a target material, a processing speed may vary depending on the physical properties of the material. For example, even after a copper pad is exposed, the copper pad may be further exposed to an abrasive for a considerable amount of time to process an insulating material around the copper pad because the insulating material used for a thin package is processed at a slower speed than copper. This may cause a problem in that copper may be easily milled or lifted.

### SUMMARY

An aspect of the present disclosure may provide a printed circuit board capable of minimizing damage to a wiring exposed by processing for forming a cavity and a method for manufacturing the same.

Another aspect of the present disclosure may provide a printed circuit board capable of preventing a milling or lifting phenomenon caused by processing for forming a cavity and a method for manufacturing the same.

One of several solutions suggested through the present disclosure is to form a metal layer in advance on a wiring layer disposed in a region to be processed for forming a cavity, and remove the metal layer after the cavity is formed, so that the cavity can be formed while protecting the wiring layer.

According to an aspect of the present disclosure, a printed circuit board may include: a first insulating layer; a first wiring layer disposed on an upper surface of the first insulating layer, and including a first wiring portion and a second wiring portion; and a second insulating layer disposed on the upper surface of the first insulating layer, having a cavity exposing an upper surface of the second wiring portion, and including a first insulating portion covering the first wiring portion and a second insulating portion whose upper surface is exposed from the cavity, wherein one or more gaps are formed between the second wiring portion and the second insulating portion.

According to another aspect of the present disclosure, a method for manufacturing a printed circuit board may include: forming a first wiring layer on an upper surface of a first insulating layer, the first wiring layer including a first wiring portion and a second wiring portion; forming a metal layer on surfaces of the second wiring portion; forming a second insulating layer on the upper surface of the first insulating layer, the second insulating layer including a first insulating portion covering the first wiring portion and a second insulating portion covering the second wiring portion; forming a cavity in the second insulating layer, the cavity exposing an upper surface of the second wiring portion and an upper surface of the second insulating portion; and removing the metal layer.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating an example of a printed circuit board;

FIG. 4 is a schematic plan view of the printed circuit board of FIG. 3 when viewed from above; and

FIGS. 5A through 5J are schematic views illustrating examples of processes for manufacturing the printed circuit board of FIG. 3.

### DETAILED DESCRIPTION

Hereinafter, exemplary embodiments of the present disclosure will now be described in detail with reference to the accompanying drawings.

### Electronic Device

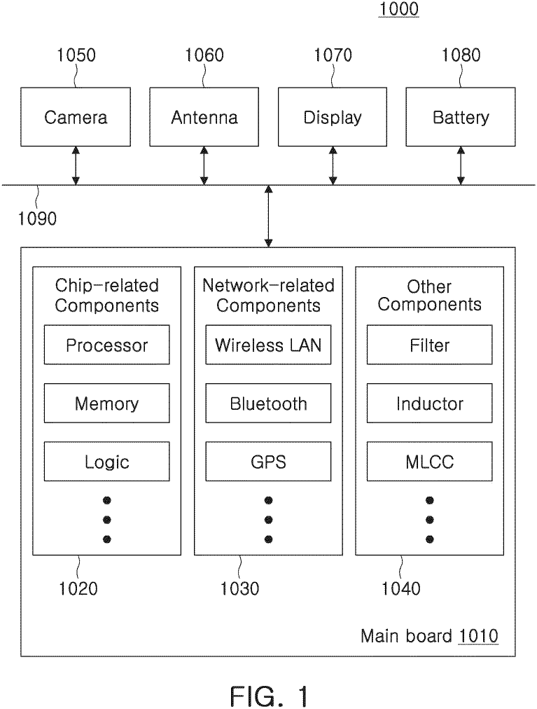

FIG. 1 is a schematic block diagram illustrating an example of an electronic device system.

Referring to FIG. 1, an electronic device 1000 may accommodate a mainboard 1010 therein. The mainboard 1010 may include chip-related components 1020, network-related components 1030, and other components 1040, physically and/or electrically connected thereto. These components may be connected to other electronic components to be described below to form various signal lines 1090.

The chip-related components 1020 may include a memory chip such as a volatile memory (e.g., a dynamic random access memory (DRAM) ) , a non-volatile memory (e.g. , a read only memory (ROM) ), or a flash memory; an application processor chip such as a central processor (e.g., a central processing unit (CPU) ) , a graphics processor (e.g., a graphics processing unit (GPU) ) a digital signal processor, a cryptographic processor, a microprocessor, or a microcontroller; and a logic chip such as an analog-digital converter or an application-specific integrated circuit (ASIC). The chip-related components 1020 are not limited thereto, but may also include other types of chip-related electronic components. In addition, the chip-related components 1020 may be combined with each other. The chip-related components 1020 may be in the form of a package including the chips or electronic components described above.

The network-related components 1030 may include protocols such as wireless fidelity (Wi-Fi) (Institute of Electrical and Electronics Engineers (IEEE) 802.11 family or the like), worldwide interoperability for microwave access (WiMAX) (IEEE 802.16 family or the like) , IEEE 802.20, long term evolution (LTE) , evolution data only (Ev-DO) , high speed packet access + (HSPA+) , high speed downlink packet access + (HSDPA+) , high speed uplink packet access + (HSUPA+), global system for mobile communications (GSM), enhanced data GSM environment (EDGE), global positioning system (GPS), general packet radio service (GPRS), code division multiple access (CDMA), time division multiple access (TDMA), digital enhanced cordless telecommunications (DECT) , Bluetooth, 3G, 4G, and 5G protocols, and any other wireless and wired protocols designated after the abovementioned protocols. However, the network-related components 1030 are not limited thereto, but may also include a variety of other wireless or wired standards or protocols. In addition, the network-related components 1030 may be combined with each other, together with the chip-related components 1020.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, but also include passive elements in chip component type used for various other purposes, and the like. In addition, the other components 1040 may be combined with each other, together with the chip-related components 1020 and/or the network-related components 1030.

Depending on the type of electronic device 1000, the electronic device 1000 may include other electronic components that may or may not be physically and/or electrically connected to the mainboard 1010. Examples of the other electronic components may include a camera 1050, an antenna 1060, a display 1070, a battery 1080, and the like. The other electronic components are not limited thereto, but may be an audio codec, a video codec, a power amplifier, a compass, an accelerometer, a gyroscope, a speaker, a mass storage unit (e.g., a hard disk drive), a compact disk (CD), a digital versatile disk (DVD), and the like. The other electronic components may also include other electronic components and the like used for various purposes depending on the type of electronic device 1000.

The electronic device 1000 may be a smartphone, a personal digital assistant (PDA) , a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

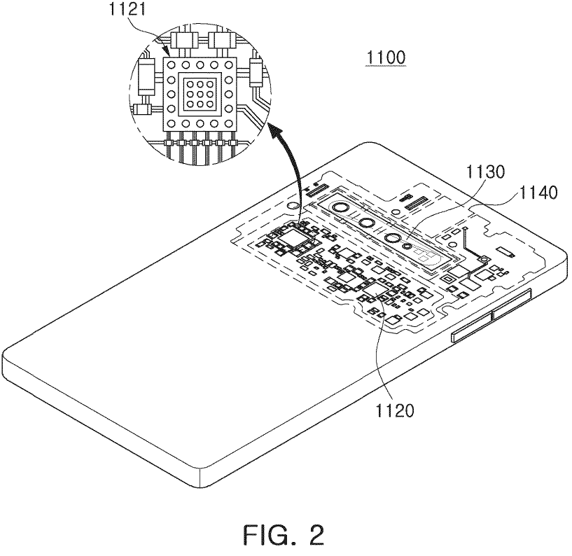

FIG. 2 is a schematic perspective view illustrating an example of an electronic device.

Referring to FIG. 2, the electronic device may be, for example, a smartphone 1100. A motherboard 1110 may be accommodated in the smartphone 1100, and various components 1120 may be physically and/or electrically connected to the motherboard 1110. Also, other components that may or may not be physically and/or electrically connected to the motherboard 1110, such as a camera module 1130 and/or a speaker 1140, may be accommodated in the smartphone 1100. Some of the components 1120 may be the above-described chip-related components, e.g., a component package 1121, but are not limited thereto. The component package 1121 may be in the form of a printed circuit board on which electronic components including active components and/or passive components are surface-mounted, but is not limited thereto. Alternatively, the component package 1121 may be in the form of a printed circuit board in which active components and/or passive components are embedded. Meanwhile, the electronic device is not necessarily limited to the smartphone 1100, but may be any other electronic device as described above.

### Printed Circuit Board

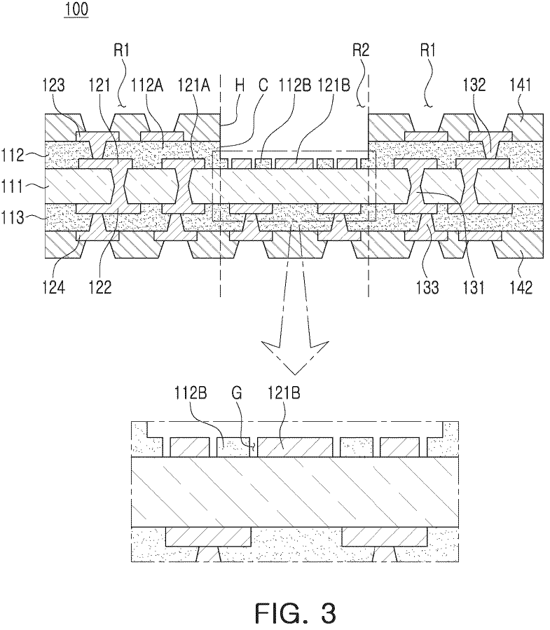

FIG. 3 is a schematic cross-sectional view illustrating an example of a printed circuit board.

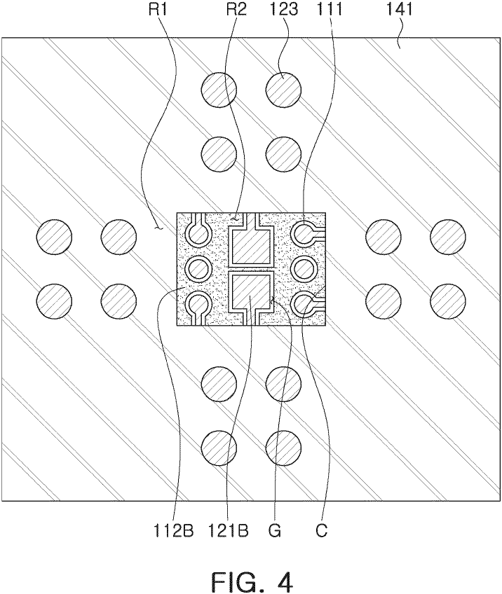

FIG. 4 is a schematic plan view of the printed circuit board of FIG. 3 when viewed from above.

Referring to FIGS. 3 and 4, a printed circuit board 100 according to an exemplary embodiment may include a first insulating layer 111, a first wiring layer 121 disposed on an upper surface of the first insulating layer 111, and a second insulating layer 112 disposed on the upper surface of the first insulating layer 111 to cover the first wiring layer 121. The second insulating layer 112 may have a cavity C. The first wiring layer 121 may include a first wiring portion 121A disposed in a first region R1 where the cavity C is not formed, and a second wiring portion 121B disposed in a second region R2 where the cavity C is formed such that an upper surface thereof is exposed from the cavity C. The second insulating layer 112 may include a first insulating portion 112A disposed in the first region R1 to cover the first wiring portion 121A, and a second insulating portion 112B disposed in the second region R2 such that an upper surface thereof is exposed from the cavity C. One or more gaps G may be formed between the second wiring portion 121B and the second insulating portion 112B.

As described above, in a general cavity processing method such as blast processing, since a cavity is formed by physically damaging a target material, a processing speed may vary depending on the physical properties of the material. For example, even after a copper pad is exposed, the copper pad may be further exposed to an abrasive for a considerable amount of time to process an insulating material around the copper pad because the insulating material used for a thin package is processed at a slower speed than copper. This may cause a problem that copper is easily milled or lifted.

In contrast, in the printed circuit board 100 according to an exemplary embodiment, a metal layer including nickel (Ni) or the like may be formed in advance on the second wiring portion 121B of the first wiring layer 121 disposed in a region to be processed for forming a cavity C through surface treatment, e.g. , surface plating, as in a process to be described below to protect the second wiring portion 121B, and the metal layer may be removed after the cavity C is formed. As a result, one or more gaps G may be formed between the second wiring portion 121B and the second insulating portion 112B, whose upper surfaces are exposed from the cavity C, while the metal layer is removed. In this way, the second wiring portion 121B can be protected at the time of processing for forming the cavity C, thereby minimizing damage and effectively preventing a milling or lifting phenomenon accordingly.

Meanwhile, each of the one or more gaps G may be connected to the cavity C. In addition, the one or more gaps G may expose the upper surface of the first insulating layer 111. In a case where one or more gaps G are formed in such a form, it is possible to minimize damage to the second wiring portion 121B at the time of processing for forming the cavity C, thereby more effectively preventing the milling or lifting phenomenon.

Meanwhile, the cavity C may penetrate through a portion of the second insulating layer 112 in a thickness direction, and thus, a side surface of the first insulating portion 112A may be exposed from the cavity C, while the upper surface of the second insulating portion 112B may be exposed from the cavity C. As a result, the upper surface of the second insulating portion 112B may have a step difference from an upper surface of the first insulating portion 112A, and may be substantially coplanar with the upper surface of the second wiring portion 121B. In a case where the cavity C is formed in this form, it is possible to minimize damage to the second wiring portion 121B at the time of processing for forming the cavity C, thereby more effectively preventing the milling or lifting phenomenon.

Meanwhile, electronic components may be disposed in the cavity C. The electronic components may be active components and/or passive components. The active component may be various types of integrated circuit dies. The passive components may be various types of chips . Thus, the second wiring portion 121B may include pads for mounting the electronic components thereon. The pads may be variously changed in shape, number, size, etc. depending on design.

Meanwhile, the printed circuit board 100 according to an exemplary embodiment may further include a second wiring layer 122 disposed on a lower surface of the first insulating layer 111, a first via layer 131 penetrating through the first insulating layer 111 to electrically connect the first and second wiring layers 121 and 122 to each other, a third insulating layer 113 disposed on the lower surface of the first insulating layer 111 to cover the second wiring layer 122, a third wiring layer 123 disposed on an upper surface of the second insulating layer 112, a fourth wiring layer 124 disposed on a lower surface of the third insulating layer 113, a second via layer 132 penetrating through the second insulating layer 112 to electrically connect the first and third wiring layers 121 and 123 to each other, and/or a third via layer 133 penetrating through the third insulating layer 113 to electrically connect the second and fourth wiring layers 122 and 124 to each other. In this way, the printed circuit board 100 may be in the form of a multilayer core substrate. However, the printed circuit board 100 is not limited thereto, and may be in the form of a multilayer coreless substrate. In addition, the printed circuit board 100 may have a greater number of layers.

If necessary, a cavity C may also be formed in the third insulating layer 113, and in this case, what has been described above concerning the cavity C is substantially identically applicable. For example, the second wiring layer 122 may also include a configuration corresponding to the first and second wiring portions, and the third insulating layer 113 may also include a configuration corresponding to the first and second insulating portions. Also, a configuration corresponding to the one or more gaps G may be formed.

Meanwhile, the printed circuit board 100 according to an exemplary embodiment may further include a first passivation layer 141 disposed on the upper surface of the second insulating layer 112 to cover the third wiring layer 123 and having a plurality of openings exposing at least portions of a partial upper surface of the third wiring layer 123, respectively, and/or a second passivation layer 142 disposed on the lower surface of the third insulating layer 113 to cover the fourth wiring layer 124 and having a plurality of openings exposing at least portions of a partial lower surface of the fourth wiring layer 124, respectively. In this way, protective layers protecting the internal components may be disposed on the outermost sides of the printed circuit board 100. The first passivation layer 141 may have a through hole H exposing the cavity C. The through hole H may be connected to the cavity C.

Hereinafter, the components of the printed circuit board 100 according to an exemplary embodiment will be described in more detail with reference to FIGS. 3 and 4.

The first insulating layer 111 may be a core layer. The first insulating layer 111 may include an insulating material. The insulating material may include a thermosetting resin such as an epoxy resin, a thermoplastic resin such as a polyimide resin, or a material including an inorganic filler, an organic filler, and/or a glass fiber together with the thermosetting or thermoplastic resin. For example, the applicable insulating material may be prepreg (PPG) or the like, which may be introduced through copper clad laminate (CCL) or the like, but is not limited thereto, and may include another type of polymer material.

The second and third insulating layers 112 and 113 may be build-up layers. Each of the second and third insulating layers 112 and 113 may include an insulating material. The insulating material may include a thermosetting resin such as an epoxy resin, a thermoplastic resin such as a polyimide resin, or a material including an inorganic filler, an organic filler, and/or a glass fiber together with the thermosetting or thermoplastic resin. For example, the applicable insulating material may be PPG, Ajinomoto build-up film (ABF), or the like, which may be introduced through resin coated copper (RCC), but is not limited thereto, and may include another type of polymer material.

Each of the first to fourth wiring layers 121 to 124 may include a metal material. The metal material may include copper (Cu), aluminum (Al), silver (Ag), tin (Sn), gold (Au), nickel (Ni), lead (Pb), titanium (Ti), and/or an alloy thereof. Each of the first to fourth wiring layers 121 to 124 may perform various functions depending on how to the wiring layers are designed. For example, the first to fourth wiring layers 121 to 124 may include ground patterns, power patterns, signal patterns, or the like. Here, the signal patterns may include various signals, e.g., data signals, other than ground patterns, power patterns, and the like. Each of these patterns may include a line pattern, a plane pattern, and/or a pad pattern. Each of the first to fourth wiring layers 121 to 124 may include an electroless plating layer (or chemical copper) and an electrolytic plating layer (or electrical copper). If necessary, each of the first to fourth wiring layers 121 to 124 may further include a copper foil layer.

The first via layer 131 may electrically connect the first and second wiring layers 121 and 122 to each other, and as a result, an electrical path may be formed in the printed circuit board 100. The first via layer 131 may perform various functions depending on design. For example, the first via layer 131 may include a ground through via, a power through via, a signal through via, or the like. The first via layer 131 may include a plurality of through vias. The through via of the first via layer 131 may include a conductive material, particularly a metal material, such as copper (Cu), aluminum (Al), silver (Ag), tin (Sn), gold (Au), nickel (Ni), lead (Pb), titanium (Ti), or an alloy thereof . The through via of the first via layer 131 may include an electroless plating layer (or chemical copper) and an electrolytic plating layer (or electrical copper) . If necessary, the through via of the first via layer 131 may further include a copper foil layer. The through via of the first via layer 131 may be of a type in which a via hole is filled with the conductive material, or may be of a conformal type in which the conductive material is disposed along a wall surface of a via hole. The through via of the first via layer 131 may have a cylindrical shape or an hourglass shape .

The second and third via layers 132 and 133 may electrically connect the first to fourth wiring layers 121 to 124 formed in different layers to each other, and as a result, an electrical path may be formed in the printed circuit board 100. The second and third via layers 132 and 133 may perform various functions depending on how the via layers are designed. For example, each of the second and third via layers 132 and 133 may include a ground connection via, a power through via, a signal through via, or the like. Each of the second and third via layers 132 and 133 may include a plurality of connection vias. The connection via of each of the second and third via layers 132 and 133 may include a conductive material, particularly a metal material, such as copper (Cu), aluminum (Al), silver (Ag), tin (Sn), gold (Au), nickel (Ni), lead (Pb), titanium (Ti), or an alloy thereof. The connection via of each of the second and third via layers 132 and 133 may include an electroless plating layer (or chemical copper) and an electrolytic plating layer (or electrical copper). If necessary, the connection via of each of the second and third via layers 132 and 133 may further include a copper foil layer. The connection via of each of the second and third via layers 132 and 133 may be of a type in which a via hole is filled with the conductive material, or may be of a conformal type in which the conductive material is disposed along a wall surface of a via hole. The connection via of each of the second and third via layers 132 and 133 may have a tapered shape.

The first and second passivation layers 141 and 142 may be disposed on the outermost sides of the printed circuit board 100 to protect internal components. A material used for the first and second passivation layers 141 and 142 is not particularly limited. For example, an insulating material may be used, and in this case, a solder resist may be used as the insulating material. However, the material used for the first and second passivation layers 141 and 142 is not limited thereto, and may be ABF or the like.

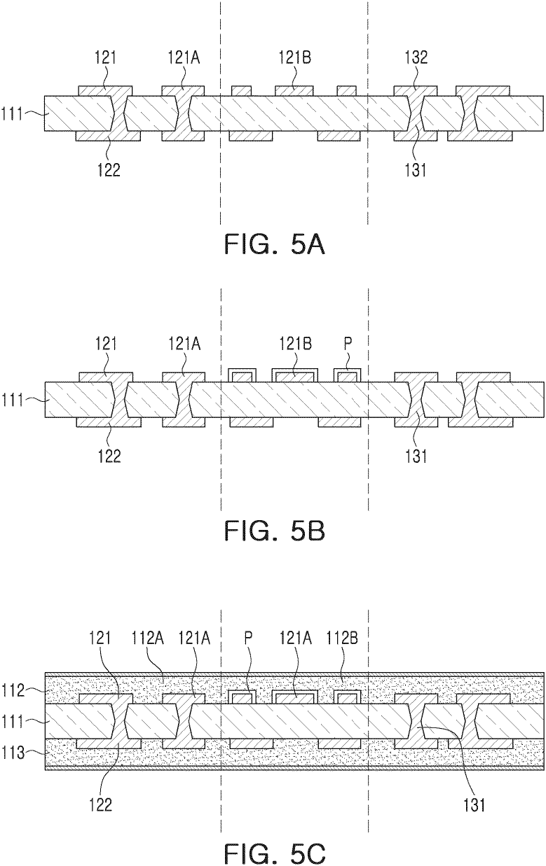

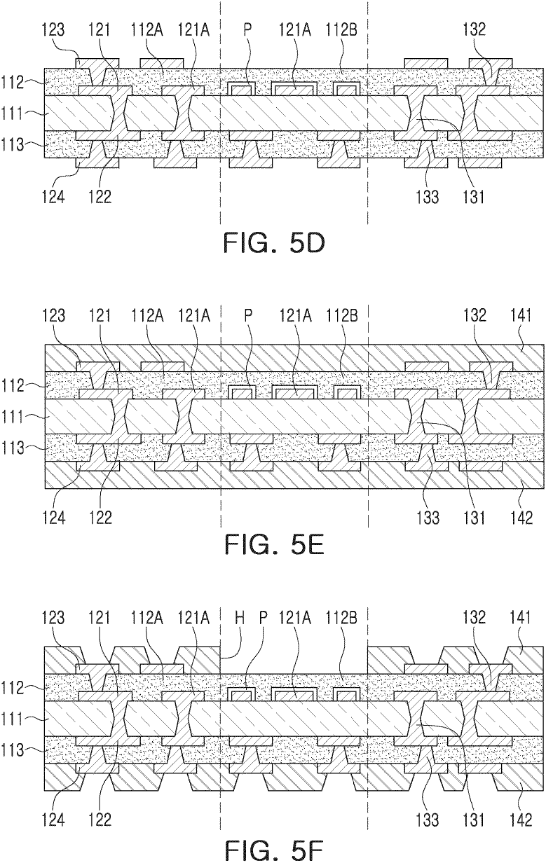

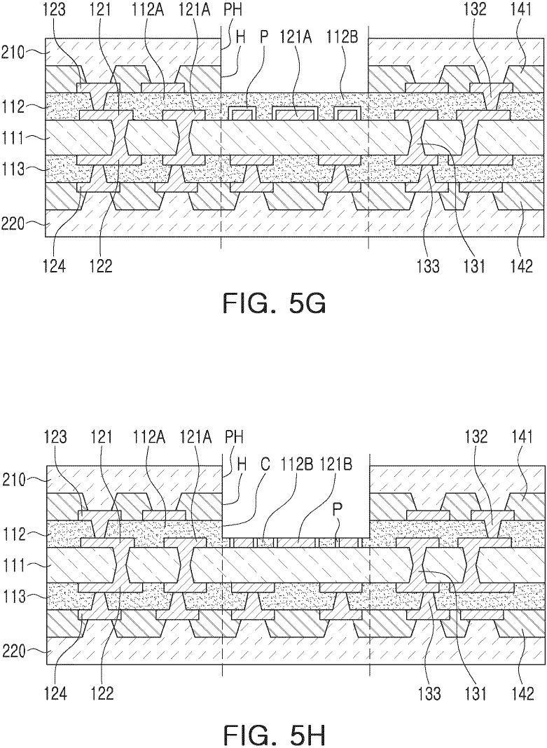

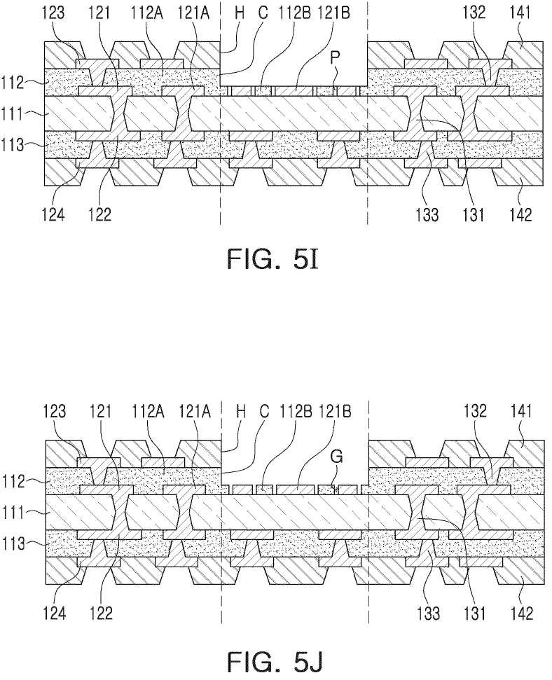

FIGS. 5A through 5J are schematic views illustrating examples of processes for manufacturing the printed circuit board of FIG. 3.

Referring to FIG. 5A, a first wiring layer 121 including a first wiring portion 121A and a second wiring portion 121B may be formed on an upper surface of a first insulating layer 111. If necessary, a second wiring layer 122 may be further formed on a lower surface of the first insulating layer 111. In addition, a first via layer 131 penetrating through the first insulating layer 111 may be further formed to electrically connect the first and second wiring layers 121 and 122 to each other. Each of the first and second wiring layers 121 and 122 and the first via layer 131 may be formed through a plating process using an additive process (AP), a semi AP (SAP), a modified SAP (MSAP), tenting (TT), or the like. A via hole for forming the first via layer 131 may be formed using laser processing, drill processing, or the like.

Referring to FIG. 5B, a metal layer P may be formed on surfaces of the second wiring portion 121B. The metal layer P may be formed by plating the surface of the second wiring portion 121B using a metal, e.g., nickel (Ni), different from a metal included in the first wiring layer 121, e.g., copper (Cu). Electrolytic plating or electroless plating may be used as plating. For example, the metal layer P may be a nickel (Ni) plating layer, but is not limited thereto.

Referring to FIG. 5C, a second insulating layer including a first insulating portion 112A covering the first wiring portion 121A and a second insulating portion 112B covering the second wiring portion 121B may be formed on the upper surface of the first insulating layer 111. If necessary, a third insulating layer 113 covering the second wiring layer 122 may be further formed on the lower surface of the first insulating layer 111. The second and third insulating layers 112 and 113 may be formed by laminating RCC and curing the RCC if necessary.

Referring to FIG. 5D, if necessary, a third wiring layer 123 may be further formed on an upper surface of the second insulating layer 112. Also, a fourth wiring layer 124 may be further formed on a lower surface of the third insulating layer 113. In addition, a second via layer 132 penetrating through the second insulating layer 112 may be further formed to electrically connect the first and third wiring layers 121 and 123 to each other. Also, a third via layer 133 penetrating through the third insulating layer 113 may be further formed to electrically connect the second and fourth wiring layers 122 and 124 to each other. Each of the third and fourth wiring layers 123 and 124 and the second and third via layers 132 and 133 may be formed by a plating process using AP, SAP, MSAP, TT, or the like. Each of via holes for forming the second and third via layers 132 and 133 may be formed using laser processing, drill processing, or the like.

Referring to FIG. 5E, if necessary, a first passivation layer 141 covering the third wiring layer 123 may be further formed on the upper surface of the second insulating layer 112. Also, a second passivation layer 142 covering the fourth wiring layer 124 may be further formed on the lower surface of the third insulating layer 113. Each of the first and second passivation layers 141 and 142 may be formed by applying a solder resist material, or by laminating an uncured solder resist layer and then curing the solder resist layer.

Referring to FIG. 5F, if necessary, a plurality of openings may be formed in each of the first and second passivation layers 141 and 142. In addition, a through hole H exposing the second insulating portion 112B may be formed in the first passivation layer 141. The plurality of openings and the through hole H may be formed using a photolithography process, for example, exposure and development.

Referring to FIG. 5G, if necessary, first and second dry films 210 and 220 may be further formed on the first and second passivation layers 141 and 142, respectively. The first dry film 210 may have a pattern hole PH exposing the through hole H. The pattern hole PH may be formed using a photolithography process, for example, exposure and development.

Referring to FIG. 5H, a cavity C exposing an upper surface of the second wiring portion 121B and an upper surface of the second insulating portion 112B may be formed in the second insulating layer 112. The cavity C may be formed by blast processing. The metal layer P formed on the upper surface of the second wiring portion 121B may be polished and removed by blast processing. At the time of processing for forming the cavity C, surfaces of the metal layer P may serve as a mask, thereby preventing the second wiring portion 121B from being milled or lifted while the soft second insulating layer 112 is processed by blasting. The blast processing may continue until the surfaces of the second wiring portion 121B are exposed, and thus, the upper surface of the second wiring portion 121B and the upper surface of the second insulating portion 112B may be substantially coplanar with each other after being processed.

Referring to FIG. 5I, if necessary, the first and second dry films 210 and 220 may be removed. The first and second dry films 210 and 220 may be removed by processing using a developer.

Referring to FIG. 5J, the metal layer P may be removed. The metal layer P may be removed by etching. The metal layer P formed on a side surface of the second wiring portion 121B may be removed by etching. As a result, the above-described one or more gaps G may be formed between the second wiring portion 121B and the second insulating portion 112B.

Through a series of processes, the printed circuit board 100 according to an exemplary embodiment described above may be manufactured. However, this is merely an example of a manufacturing method, and the printed circuit board 100 according to an exemplary embodiment described above may be manufactured by another manufacturing method.

Concerning the other details, the details described above for the printed circuit board 100 according to an exemplary embodiment may also be applicable to the method for manufacturing a printed circuit board according to an exemplary embodiment unless contradictory, and the overlapping description will be omitted.

As set forth above, as one effect of the present disclosure, it is possible to provide a printed circuit board capable of minimizing damage to a wiring exposed by processing for forming a cavity and a method for manufacturing the same.

As another effect of the present disclosure, it is possible to provide a printed circuit board capable of preventing a milling or lifting phenomenon caused by processing for forming a cavity and a method for manufacturing the same.

While exemplary embodiments have been shown and described above, it will be apparent to those skilled in the art that modifications and variations could be made without departing from the scope of the present invention as defined by the appended claims.

What is claimed is:

1. A printed circuit board comprising:
a first insulating layer;
a first wiring layer disposed on an upper surface of the first insulating layer, and including a first wiring portion and a second wiring portion; and
a second insulating layer disposed on the upper surface of the first insulating layer, having a cavity exposing an upper surface of the second wiring portion, and including a first insulating portion covering the first wiring portion and a second insulating portion whose upper surface is exposed from the cavity,
wherein one or more gaps are provided between the second wiring portion and the second insulating portion.

2. The printed circuit board of claim 1, wherein each of the one or more gaps is connected to the cavity.

3. The printed circuit board of claim 2, wherein each of the one or more gaps exposes the upper surface of the first insulating layer.

4. The printed circuit board of claim 1, wherein the cavity penetrates through a portion of the second insulating layer in a thickness direction of the printed circuit board, and
a side surface of the first insulating portion is exposed from the cavity.

5. The printed circuit board of claim 1, wherein an upper surface of the first insulating portion has a step difference from the upper surface of the second insulating portion.

6. The printed circuit board of claim 1, wherein the upper surface of the second wiring portion is substantially coplanar with the upper surface of the second insulating portion.

7. The printed circuit board of claim 1, further comprising:
a second wiring layer disposed on a lower surface of the first insulating layer;
a first via layer penetrating through the first insulating layer to connect the first and second wiring layers to each other; and
a third insulating layer disposed on the lower surface of the first insulating layer to cover the second wiring layer.

8. The printed circuit board of claim 7, further comprising:
a third wiring layer disposed on an upper surface of the second insulating layer;
a fourth wiring layer disposed on a lower surface of the third insulating layer;
a second via layer penetrating through the second insulating layer to connect the first and third wiring layers to each other; and
a third via layer penetrating through the third insulating layer to connect the second and fourth wiring layers to each other.

9. The printed circuit board of claim 8, further comprising:
a first passivation layer disposed on the upper surface of the second insulating layer to cover the third wiring layer, and having a plurality of openings exposing at least portions of an upper surface of the third wiring layer, respectively; and
a second passivation layer disposed on the lower surface of the third insulating layer to cover the fourth wiring layer, and having a plurality of openings exposing at least portions of a lower surface of the fourth wiring layer, respectively,
wherein the first passivation layer has a through hole connected to the cavity.

10. A method for manufacturing a printed circuit board, the method comprising:
forming a first wiring layer on an upper surface of a first insulating layer, the first wiring layer including a first wiring portion and a second wiring portion;
forming a metal layer on surfaces of the second wiring portion;
forming a second insulating layer on the upper surface of the first insulating layer, the second insulating layer including a first insulating portion covering the first wiring portion and a second insulating portion covering the second wiring portion; and
forming a cavity in the second insulating layer to expose an upper surface of the second wiring portion and an upper surface of the second insulating portion; and
removing the metal layer.

11. The method of claim 10, wherein the forming of the metal layer includes plating the surfaces of the second wiring portion using a metal different from a metal included in the first wiring layer, and
the metal layer is formed on the upper surface and side surfaces of the second wiring portion by the plating.

12. The method of claim 11, wherein the metal included in the first wiring layer includes copper (Cu), and
the metal different from the metal included in the first wiring layer includes nickel (Ni).

13. The method of claim 10, wherein the forming of the cavity includes processing the second insulating layer by blasting, and
the metal layer formed on the upper surface of the second wiring portion is removed by the blasting.

14. The method of claim 13, wherein the removing of the metal layer includes etching the metal layer formed on side surfaces of the second wiring portion.

15. The method of claim 10, further comprising, before the forming of the metal layer:
forming a second wiring layer on a lower surface of the first insulating layer; and
forming a first via layer penetrating through the first insulating layer to connect the first and second wiring layers to each other.

16. The method of claim 15, further comprising, after the forming of the metal layer:
forming a third insulating layer covering the second wiring layer on the lower surface of the first insulating layer;
forming a third wiring layer on an upper surface of the second insulating layer;
forming a second via layer penetrating through the second insulating layer to connect the first and third wiring layers to each other;
forming a fourth wiring layer on a lower surface of the third insulating layer; and
forming a third via layer penetrating through the third insulating layer to connect the second and fourth wiring layers to each other.

17. The method of claim 16, further comprising, before the forming of the cavity:
forming a first passivation layer covering the third wiring layer on the upper surface of the second insulating layer;
forming a second passivation layer covering the fourth wiring layer on the lower surface of the third insulating layer; and
forming a through hole in the first passivation layer to expose the upper surface of the second insulating portion.

18. A printed circuit board comprising:
a first insulating layer;
a first wiring layer disposed on an upper surface of the first insulating layer, and including a first wiring portion and a second wiring portion; and
a second insulating layer disposed on the upper surface of the first insulating layer, having a cavity extending from the second wiring portion, and including a first insulating portion in contact with the first wiring portion and a second insulating portion disposed in a region of the cavity and spaced apart from the second wiring portion.

19. The printed circuit board of claim 18, wherein the cavity penetrates through a portion of the second insulating layer in a thickness direction of the printed circuit board, and
a side surface of the first insulating portion is exposed from the cavity.

20. The printed circuit board of claim 18, wherein the first insulating portion has a step difference from the second insulating portion.

21. The printed circuit board of claim 18, further comprising:
a third wiring layer disposed on an upper surface of the second insulating layer; and
a second via layer penetrating through the second insulating layer to connect the first and third wiring layers to each other.

22. The printed circuit board of claim 21, further comprising:
a passivation layer disposed on the upper surface of the second insulating layer to cover the third wiring layer, and having a plurality of openings exposing at least portions of an upper surface of the third wiring layer, respectively; and
wherein the passivation layer has a through hole connected to the cavity.
